(19) United States
(12) Patent Application Publication
(10) Pub. No.: US 2024/0220703 A1
(43) Pub. Date: Jul. 4, 2024

(54) DEVICE, METHOD, AND COMPUTER-READABLE MEDIUM FOR FORMAL VERIFICATION OF A CIRCUIT DESIGN

(71) Applicants: Samuel COWARD, London (GB); Theo DRANE, El Dorado Hills, CA (US); George CONSTANTINIDES, London (GB)

(72) Inventors: Samuel COWARD, London (GB); Theo DRANE, El Dorado Hills, CA (US); George CONSTANTINIDES, London (GB)

(21) Appl. No.: 18/395,753

(22) Filed: Dec. 26, 2023

Related U.S. Application Data
(60) Provisional application No. 63/505,264, filed on May 31, 2023.

(51) Int. Cl. G06F 30/398

(52) U.S. Cl. CPC G06F 30/398

(57) ABSTRACT

A device, method, and non-transitory computer-readable medium for generating one or more equivalent designs between a first and second circuit designs. Graphs for the first and second design are created each consisting of vertices representing operators and operands, with edges representing relationships between them. These graphs are combined into a third graph that is modified to include multiple logically equivalent designs to the original two designs by determining equivalent operators for certain vertices. From the logically equivalent designs in the third graph, a set of shared designs is extracted, consisting of vertices that are common between the equivalent designs in the first and second graphs. These shared designs may be expressed in a register transfer level (RTL) representation for validation and equivalence checking.

### CROSS-REFERENCE TO RELATED APPLICATION

This application claims priority to U.S. Provisional Application 63/505,264, filed on May 31, 2023. The content of this earlier filed application is incorporated by reference herein in its entirety.

### BACKGROUND

The process of designing and testing of hardware circuits is often performed through different levels of abstraction, from high-level hardware description languages to the low-level design of the transistors and other components. One abstraction level is the so-called register transfer level (RTL) abstraction level, which is used in hardware description languages like Verilog or VHDL (Very High Speed Integrated Circuits Hardware Description Language). A representation of a circuit on the RTL abstraction level is subsequently synthesized to a netlist, and ultimately to a circuit design.

In order to formally verify the circuit design, automated tools called equivalence checkers are used. Commercial RTL equivalence checking tools deploy word-level rewrites as an essential tool to automate verification. However, it is typically unclear which rewrites to apply and in what order to apply them to find a path between architectures. Therefore, an improved concept for word-level, equivalence-graph rewriting may be desired.

### BRIEF DESCRIPTION OF THE FIGURES

Some examples of apparatuses and/or methods will be described in the following by way of example only, and with reference to the accompanying figures, in which

FIG. 1a shows a block diagram of an example of an apparatus or device for generating a register transfer level representation of a circuit, and of a computer system comprising such an apparatus or device;

FIG. 1b shows a flow chart of an example of a method for generating a register transfer level representation of a circuit;

FIG. 2 shows an illustration of an example of equality graph rewriting;

FIG. 3 shows a flow chart of an example of a transformation of a register transfer level design into a graph representation, and of an extraction of a register transfer level representation;

FIG. 4 shows a table of an example of operators used to improve arithmetic circuits;

FIG. 5 shows a table of an example of a set of rewrites;

FIG. 6 shows code representing a specification (“spec”) and an implementation (“impl”) RTLs;

FIG. 7 shows a joint graph of the spec and impl;

FIG. 8 shows an example where, after two stages of rewriting, the e-graph contains several equivalent implementations of impl, one of which shares an operator with spec;

FIG. 9 shows an example where, after five rewriting stages, a large e-graph containing many designs is constructed; and

FIG. 10 shows spectrum visualization of designs resulting from extraction; and

FIGS. 11 to 13 shows graphs of examples of different representations of a circuit;

FIG. 14 illustrates a computing device in accordance with one implementation of the disclosed embodiments.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may be identical or implemented in a modified form while providing the same or a similar function. The thickness of lines, layers, and/or areas in the figures may also be exaggerated for clarification.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

When two elements A and B are combined using an “or,” this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a,” “an,” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include,” “including,” “comprise,” and/or “comprising,” when used, describe the presence of the specified features, integers, steps, operations, processes, elements, components, and/or a group thereof, but do not exclude the presence or addition of one or more other features, integers, steps, operations, processes, elements, components and/or a group thereof.

Unless otherwise defined, all terms (including technical and scientific terms) are used herein in their ordinary meaning of the art to which the examples belong.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform, or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

It should be noted that the example schemes disclosed herein are applicable for/with any operating system and a reference to a specific operating system in this disclosure is merely an example, not a limitation.

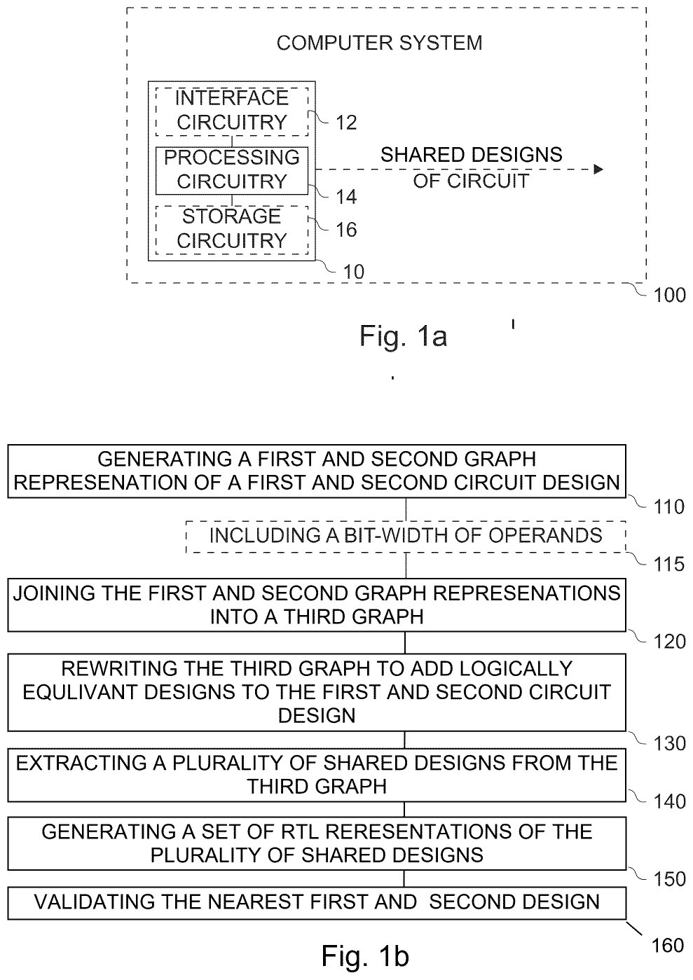

FIG. 1a shows a block diagram of an example of an apparatus 10 or device 10 for generating a plurality of shared designs relating to a first and a second design of a circuit. The apparatus 10 comprises circuitry that is configured to provide the functionality of the apparatus 10. For example, the apparatus 10 of FIGS. 1a and 1b comprises (optional) interface circuitry 12, processing circuitry 14 and (optional) storage circuitry 16. For example, the processing circuitry 14 may be coupled with the interface circuitry 12 and with the storage circuitry 16. For example, the processing circuitry 14 may be configured to provide the functionality of the apparatus, in conjunction with the interface circuitry 12 (for exchanging information, e.g., with other components of the computer system) and the storage circuitry 16 (for storing information). Likewise, the device 10 may comprise means that is/are configured to provide the functionality of the device 10. The components of the device 10 are defined as component means, which may correspond to, or implemented by, the respective structural components of the apparatus 10. For example, the device 10 of FIGS. 1a and 1b comprises means for processing 14, which may correspond to or be implemented by the processing circuitry 14, (optional) means for communicating 12, which may correspond to or be implemented by the interface circuitry 12, and (optional) means for storing information 16, which may correspond to or be implemented by the storage circuitry 16.

The processing circuitry 14 or means for processing 14 is configured to generate a graph representation of the circuit. The graph representation comprises a first set of vertices representing operators and a second set of vertices representing operands of the RTL representation of the circuit. The processing circuitry 14 or means for processing 14 is configured to determine, for one or more operators represented by the one or more vertices of the first set of vertices of the graph, one or more logically equivalent operators. The processing circuitry 14 or means for processing 14 is configured to include the one or more logically equivalent operators in the graph representation, such that the graph representation comprises a plurality of logically equivalent representations of the circuit. The processing circuitry 14 or means for processing 14 is configured to generate an RTL representation of the circuit based on one of the plurality of equivalent representations of the circuit.

FIG. 1a further shows an example of a computer system 100 comprising the apparatus 10 or device 10. The apparatus 10 may comprise processing circuitry configured to generate a first graph representation of an RTL representation of the first design and a second graph representation of an RTL representation of the second design, wherein the first and second graph representation each comprise a first set of vertices representing operators and a second set of vertices representing operands of the corresponding RTL representation, wherein each graph representation further comprises edges between the vertices representing relationships between the operators and operands. The apparatus may be configured to join the first and second graph representations into a third graph and rewrite the third graph to add a plurality of logically equivalent designs to the first and second design, wherein rewriting the third graph comprises determining, for one or more operators represented by the one or more vertices of a first set of vertices of the third graph, one or more logically equivalent operators. The apparatus may be configured to extract a plurality of shared designs from the plurality logically equivalent designs of the third graph, wherein each shared design comprises a plurality of vertices shared between the equivalent designs of the first and second graphs of the circuit.

The processing circuitry may be further configured to generate a set of RTL representations of the plurality of shared designs. The set of RTL representations may comprise a nearest first and a nearest second design. The processing circuitry may be configured to validate the first and the second design by providing the nearest first and the nearest second design to an equivalence checker. The set of RTL representations may further comprise a plurality of intermediate first and intermediate second designs. The processing circuitry may be configured to validate the first and the second design by providing the nearest and intermediate first designs and the nearest and intermediate second designs to an equivalence checker. Extracting one or more equivalent designs may comprise using an integer linear program solver. Rewriting the equivalence graph is done according to a cost function. The cost function may bias the inclusion of one or more logically equivalent operators in the equivalence graph when the operators are shared between the first and the second designs.

FIG. 1b shows a flow chart of an example of a corresponding method for generating a plurality of shared designs relating to a first and a second design of a circuit.

The method comprises generating 120 a first graph representation of an RTL representation of the first design and a second graph representation of an RTL representation of the second design. The first and second graph representation each comprise a first set of vertices representing operators and a second set of vertices representing operands of the corresponding RTL representation. Each graph representation further comprises edges between the vertices representing relationships between the operators and the operands. The method comprises joining 120 the first and second graph representations into a third graph. The method comprises rewriting 130 the third graph to add a plurality of logically equivalent designs to the first and second design. Rewriting the third graph comprises determining, for one or more operators represented by the one or more vertices of a first set of vertices of the third graph, one or more logically equivalent operators. The method comprises extracting 140 a plurality of shared designs from the plurality logically equivalent designs of the third graph. Each shared design comprises a plurality of vertices shared between the equivalent designs of the first and second graphs of the circuit.

The method, for example, may be performed by a computer system, e.g., by processing circuitry 14 of the computer system 100 shown in FIG. 1a.

In the following, the functionality of the apparatus 10, of the device 10, of the method, of a corresponding computer program, and of the computer system is illustrated with respect to the apparatus 10. Features introduced with respect to the apparatus 10 may likewise be introduced in the corresponding device, method, computer program and computer system.

The process starts with generating the graph representations of a first and second circuit design. This can occur from any source, like from a higher-abstraction level representation of the circuit such as System Verilog. Generating a graph representation may also come from another RTL representation of the circuit, for example, as defined in the Verilog or VHDL hardware description languages, which are often used to define the functionality of a circuit. In other words, the processing circuitry may be configured to generate the graph representation from a further RTL representation of the circuit.

The process continues by joining the first and second graph representations into a third graph which is an equivalence or equality graph (e-graph). An e-graph is a compact data structure representing equivalent designs by clustering equivalent expressions together. Rewrites are used to add new equivalent expression.

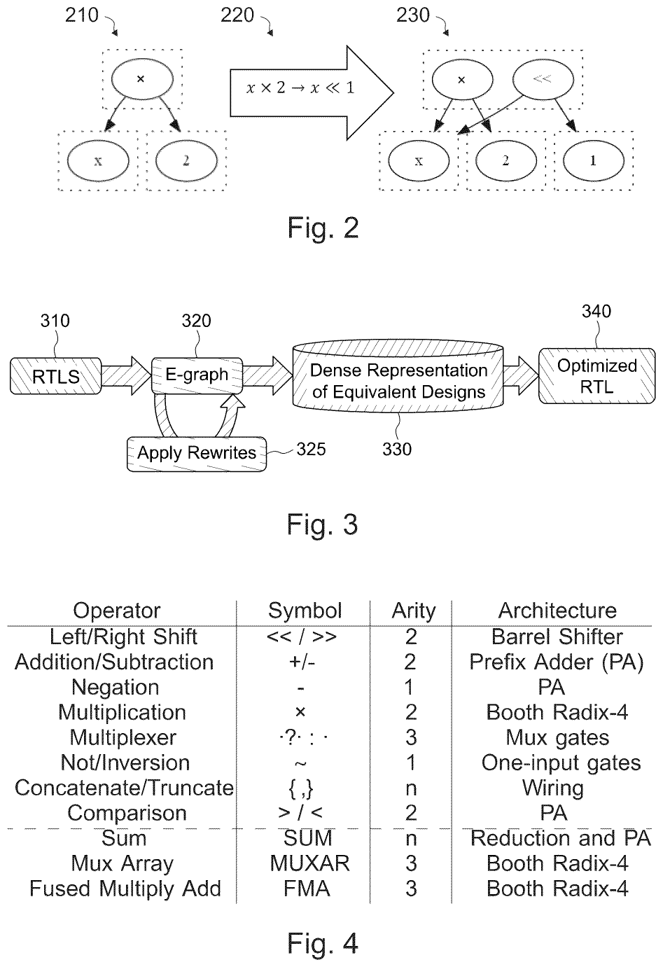

E-graphs cluster equivalent expressions into equivalence classes (e-classes), enabling a compact representation of alternative but functionally identical implementations. In the e-graph, nodes represent variables, constants or operators that point to children e-classes. Because a given sub-expression can be implemented in different ways, an e-graph can represent exponentially many implementations in the number of nodes. An e-graph is grown via constructive application of local equivalence preserving rewrites, l→r, where the right-hand side of the rewrite is added to the e-class containing l, without removing l as in a traditional rewrite engine. As a result the e-graph avoids the phase-ordering problem, where the order of application impacts the results. This approach to growing an e-graph is known as equality saturation. A simple e-graph rewriting example is shown in FIG. 2, where the dashed boxes represent e-class boundaries and the arrows connect nodes to their child e-classes.

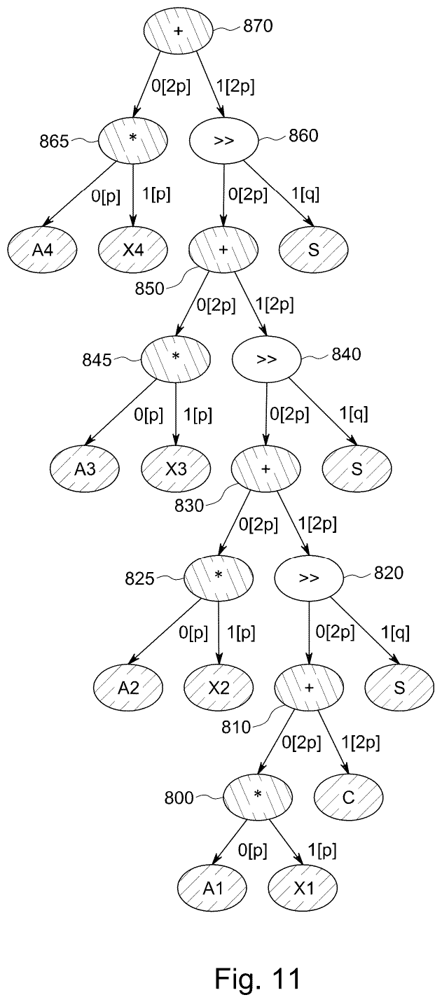

In general, the graph representations of the circuit and any e-graphs may model a data flow between the components of the circuits. For example, the graph representation may be a data-flow graph representing the circuit. The graph representation comprises two types of vertices (i.e., nodes)—vertices of the first set of vertices that represent operators, and vertices of the second set of vertices that represent operands. The vertices representing the operands are connected to the vertices representing the operators via the edges of the graph structures. Moreover, vertices representing operators may be connected to other vertices representing operators as well, with the result of an operation performed by an operator being used as operand by the other operator. Thus, the output of an operation performed by an operator may be provided as operand to another operator, or as an output of the circuit. An example of such a graph representation is given in FIGS. 11 to 13.

As can be seen in FIGS. 11 to 13, the edges between the vertices may comprise labels, such as 0[p] or 1[q]. These edge labels indicate the bit-width of the respective operator, with the “0” or “1” part indicating that the operand (or result of an operation performed by an operator) is used as 0^{th}, 1^{st} etc. operand, and the [p] or [q] part indicating the bit-width of the respective operand. In other words, the processing circuitry may be configured to include a bit-width of the operands in the graph representation as edge labels of the edges between the vertices representing the operands (or the vertices representing operators that provide an operand) and the vertices representing the operators accessing the operands. Accordingly, the first, second, and third graphs may include 115 a bit-width of the operands in the graph representation as values of the edges between the vertices representing the operands and the vertices representing the operators accessing the operands. These edge labels may later be used to determine logical equivalence between operators, with some operators only available, or efficient, for a sub-set of the supported bit-widths. The bit-widths being used may change if the proposed concept is applied to parametrizable circuit designs. In other words, circuit designs that can be adapted according to a parameter, with the parameter specifying, explicitly or implicitly, the bit-width.

In the proposed concept, the e-graph representation is extended by adding logically equivalent operators to the graphs for the first and second circuit designs. These logically equivalent operators are added as alternatives to the operators already present in the graphs. FIG. 2 illustrates a simple example e-graph.

FIG. 2 shows an example of e-graph rewriting. Nodes (the circles or ellipses) represent operators or operands, and the dashed boxes represent equivalence classes. FIG. 2 shows that the operation x<<1 is logically equivalent to x×2, and is included as another logically equivalent alternative in the graph representation. Thus, the left-hand e-graph 210 contains only x×2, but the right-hand e-graph 230 contains x×2 and x<<1, which are equivalent according to the rewrite 220.

Such a dense representation of equivalent graphs, and thus designs, by using a so-called equality graph to build the graph representation. Accordingly, the graph representation may be based on an equality graph. An equality graph is a graph that comprise multiple equivalent representations of at least a sub-graph of the graph.

For an RTL representation these e-graphs can incorporate bit-width information representing a data path RTL implementation as a dataflow graph. Using word-level bit-vector rewrites a design space of equivalent RTL implementations can be explored. This technique has been used for RTL optimization previously. See S. Coward, G. A. Constantinides and T. Drane, “Automatic Datapath Optimization using E-Graphs,” 2022 IEEE 29th Symposium on Computer Arithmetic (ARITH), Lyon, France, 2022, pp. 43-50, doi: 10.1109/ARITH54963.2022.00016.

By reformulating the initial problem setup and extraction criteria the datapath rewrites defined for optimization can be re-used to build an automatic verification assistant.

Classic formal property verification methods are not able to verify datapath dominated circuits. An alternative and successful approach is to rely on equivalence checking, where the design under test, usually called the implementation, is proven to be equivalent to a golden reference design, often called the specification. Equivalence checking defines the two circuit representations to be equivalent if for all valid inputs they generate identical outputs. The most popular equivalence checking are Boolean, Sequential, and Transactional. In Transactional equivalence checking, the result of a given computation in the implementation is compared against the result of the same computation in the trusted specification. The output of the comparison can be pass, when a property is proven, fail, when the property is not true (a counterexample is generated), or inconclusive, when the tool does not manage to either prove or disprove a property. Inconclusive results are commonplace in equivalence checking and they require the application of advanced techniques to achieve full convergence.

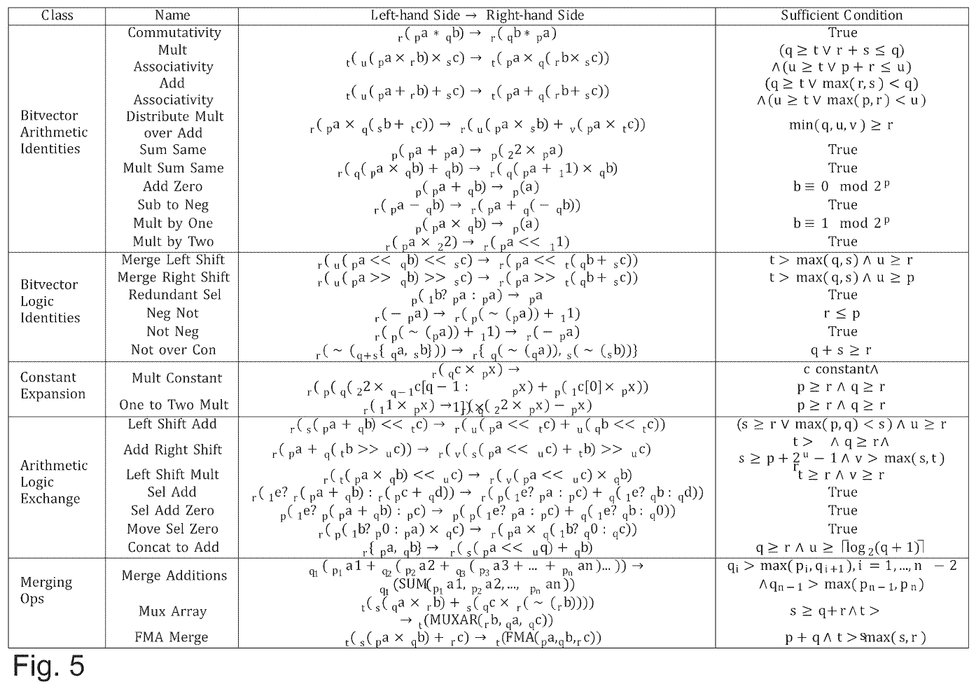

To rewrite an e-graph with the logically equivalent operators, the one or more logically equivalent operators are determined for the one or more operators represented by the one or more vertices of the first set of vertices of the graph. This may be done based on a set of rewrites, of which examples are shown in FIG. 5. In other words, the processing circuitry may be configured to determine the one or more logically equivalent operators based on a pre-defined set of logically equivalent transformations (i.e., the rewrites) between operators.

There are various types of possible logically equivalent transformations. Some logically equivalent transformations are derived from bit vector arithmetic. For example, the pre-defined set of logically equivalent transformation may comprise one or more transformations that are based on bit vector arithmetic, e.g., at least one of a transformation related to commutativity, a transformation related to multiplication associativity, a transformation related to addition associativity, a transformation related to distributing a multiplication over multiple additions, a transformation related to a sum of multiple instances of the same operand, a transformation related to a sum of multiple instances of the same operand, with one instance of the operand being part of a multiplication, a transformation related to an addition of zero, a transformation between a subtraction and an addition of a negation, a transformation related to a multiplication by one, and a transformation related to a multiplication by two. Some logically equivalent transformations may be derived from bit vector identity. For example, the pre-defined set of logically equivalent transformation may comprise one or more transformations that are based on bit vector identity, e.g., at least one of a transformation related to a merging of two left shift or two right shift operations, a transformation related to eliminating a redundant selection, a transformation between a negative value and an inverse, a transformation between an inverse and a negative value, and a transformation related to an inversion of a multiplication.

Some logically equivalent transformations may be derived from constant expansion. For example, the pre-defined set of logically equivalent transformation may comprise one or more transformations that are based on constant expansion, e.g., at least one of a transformation related to a multiplication by a constant, and a transformation related to an expansion of a multiplication of an operand by one to a multiplication of an operand by two.

Some logically equivalent transformations may be derived from arithmetic logic exchange. For example, the pre-defined set of logically equivalent transformation may comprise one or more transformations that are based on arithmetic logic exchange, e.g., at least one of a transformation related to a left or right shift applied to an addition, a transformation related to a left shift applied to a multiplication, a transformation related to expanding a selection comprising an addition, a transformation related to expanding a selection by inserting zero, a transformation related to expanding a selection by moving zero, and a transformation between a concatenation and an addition. Such exchanges may be used to substitute operators, e.g., such that an operator is replaced by another (or a group of other) operator(s). For example, the pre-defined set of logically equivalent transformations between operators may comprise at least one transformation for transforming two or more operators into two or more different operators. For example, the pre-defined set of logically equivalent transformations between operators may comprises at least one transformation for transforming a combination of a first operator and a first operand into a combination of a second operator and a second operand, with the first operator being different from the second operator and the first operand being different from the second operand. For example, a multiplication by 2ⁿ may be performed by performing a bit shift. Accordingly, the second operator may be a shift operator.

Some logically equivalent transformations may be derived from merging operators. For example, the pre-defined set of logically equivalent transformation may comprise one or more transformations that are based on merging operators, e.g., at least one of a transformation related to merging additions using a summation operator, a transformation related to multiplexing arrays, and a transformation related to a fused multiply add (FMA). These transformations are directed at merging multiple operators, e.g., by transforming multiple additions into a single summation or by using a multiplex array operation instead of two multiplications of an operand and of its inverse. Accordingly, the pre-defined set of logically equivalent transformations between operators may comprise at least one transformation for transforming two or more operators into a single operator. For example, the single operator may be one of a merge summation operator, a multiplex array operator and a fused-multiply-add operator.

Not every transformation is suitable for every bit-width. For example, some specialized operators exist with support for a limited set of bit-widths. As a consequence, the logical equivalence of the one or more logically equivalent operators may depend on the bit-width of the operands being accessed by the one or more operators. Transformations that involve such operators may thus be limited to these bit-widths (or suffer inefficiencies that occur due to additional operators required for expanding the bit-widths). Accordingly, the processing circuitry is configured to determine the one or more logically equivalent operators based on the bit-width of the operands. Moreover, not every transformation is suitable for any content of an operand. In the right column of FIG. 5, some conditions are shown that may be observed when using the proposed transformations (with “True” meaning that no conditions are imposed). These conditions may be considered to be sufficient for safely rewriting the operators, but not necessary in all cases. For example, if these conditions hold, the rewrites can be applied correctly. However, in some cases, the conditions do not hold, and the rewrites can still be applied correctly.

Once the one or more logically equivalent operators are determined, they are inserted into the graph representation, with the result of the graph representation comprising the plurality of logically equivalent representations of both circuits. These logically equivalent representations may be extracted from the graph representation, e.g., by selecting one of the logically equivalent operators wherever logically equivalent operators are included in the graph representations.

By reformulating the initial problem setup and extraction criteria the datapath rewrites defined for optimization may be reused to build an automatic verification assistant.

The present disclosure describes a method, apparatus, and computer program for representing the specification circuit design and the implementation in the same e-graph and rewriting from both directions. This enables an efficient concept for finding a path between the two designs. Even when a word-level rewriting path cannot be found, a path can still be extracted that can greatly simplify the problem for the lower abstraction level solvers. By deploying word-level equivalence graph (e-graph) rewriting, as described in present disclosure, the capabilities of these traditional tools may be substantially enhanced.

The e-graph driven rewriting method, apparatus, or engine explores in all directions simultaneously meaning there is no requirement to demine how and where to apply the given rewrites. Such a device or method may greatly simplify the manual effort of verification engineers across the industry, who typically must manually modify their designs to guarantee convergence in commercial equivalence checking tools. Moreover, this device or method may be integrated into existing solvers. Application of this method may prove cases that traditional commercial equivalence checkers are not able to prove currently.

The present disclosure relates to a concept for formal verification of a circuit design in digital hardware design. Industrial formal verification for hardware design uses automated tools called equivalence checkers. An equivalence checker aims to determine that an RTL representation of a specification circuit design is logically equivalent to an implementation of the circuit. Traditional RTL equivalence checking tools deploy word-level rewrites as an essential tool to automate verification. However, when using these tools, it is often unclear which rewrites to apply and in what order to apply them to find a path between architectures.

Some equivalence checking tools deploy e-graphs at the Boolean algebra level, as they rely on Boolean satisfiability problem or satisfiability modulo theories (SAT/SMT) solvers. Some equivalence checkers also deploy word-level rewrites but rely on traditional rewrite engine methods to determine how and when to apply the rewrites.

Bit-level e-graphs suffer from scalability issues at this low abstraction level, limiting their capabilities. Traditional word-level rewrite engines are not well suited to the verification problem as it is unclear how to apply these rewrites. The problem formulation of verification and optimization are distinct and require unique setups and inventions. The underlying bitvector manipulating rewrites can be shared.

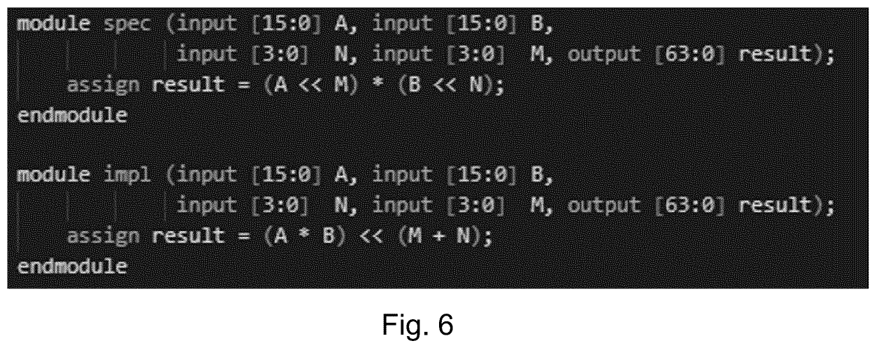

FIG. 6 shows code representing a specification (“spec”) and an implementation (“impl”) RTLs. The designs shown in FIG. 6, are alternative ways to implement floating point multiplication of denormal numbers. More precisely, given two denormals 2^{1-bias}×0.mantₐ and 2^{1-bias}×0.mant_{b}, the product of their mantissas is usually reduced to a standard non-denormal multiplication by shifting the values, expressing it as either (mantₐ<<m)×(mant_{b}<<n) or equivalently as (mantₐ×mant_{b})<<(m+n), where m=lzc(mantₐ)+1, n=lzc(mant_{b})+1 and lzc(⋅) is the leading zero counter function. The spec and impl the designs initially only share the input variables and no intermediate signals. Determining these designs to be equivalent is typically not possible with commercial validation tools.

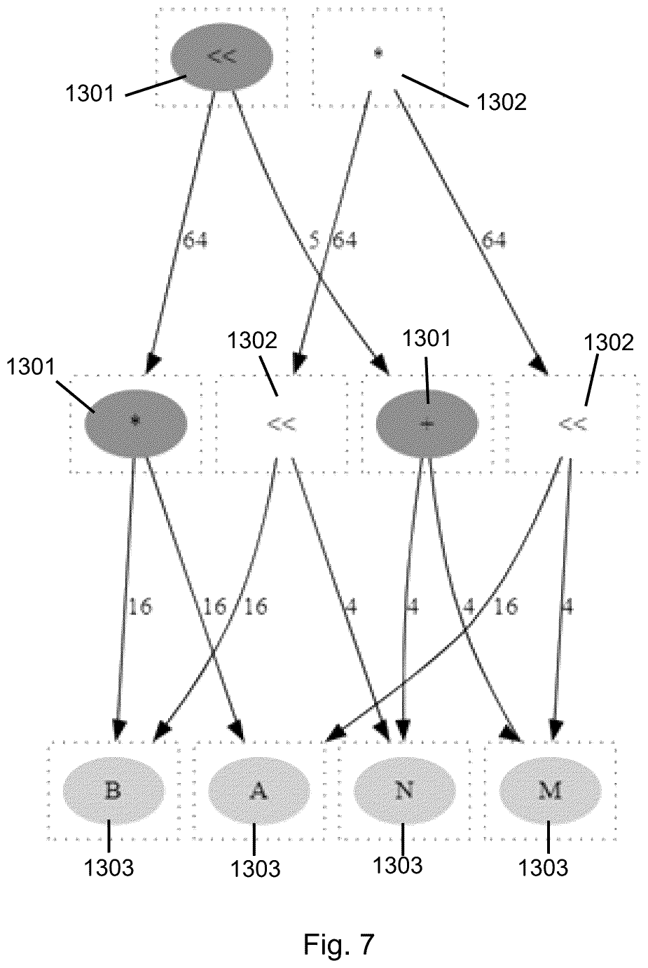

The overview of the method is to convert specification and implementation RTLs to dataflow graphs. Then an e-graph is built containing both designs, such as shown in FIG. 7. Next rewrites are applied to the e-graph to increase the number of equivalent designs. A design is extracted that shares the greatest number of operations. And finally a sequence of intermediate designs is constructed to verify the specification and implementation designs.

FIG. 7 shows a joint graph of the specification and implementation from the code of FIG. 6. The right-hand side of FIG. 7 shows an initial e-graph containing both designs—spec 1302 (light color), impl 1301 (dark color), shared 1303 (medium color). Edge labels denote bitwidths. All e-classes (dashed boxes) initially contain a single node. Initializing the e-graph with both designs allows for both designs to be simultaneously rewritten to find a common equivalent.

The rewrites define how the e-graph explores the space of equivalent designs. Bitwidth dependent rewrites described in FIG. 5, may be deployed. It is natural that the verification rewrites should include rewrites for optimization of the designs but also incorporate additional verification specific rewrites that ‘undo’ optimizations. For example, it may be productive to include transformations that introduce redundant logic that enables greater sharing of common sub-expressions between the designs in the e-graph.

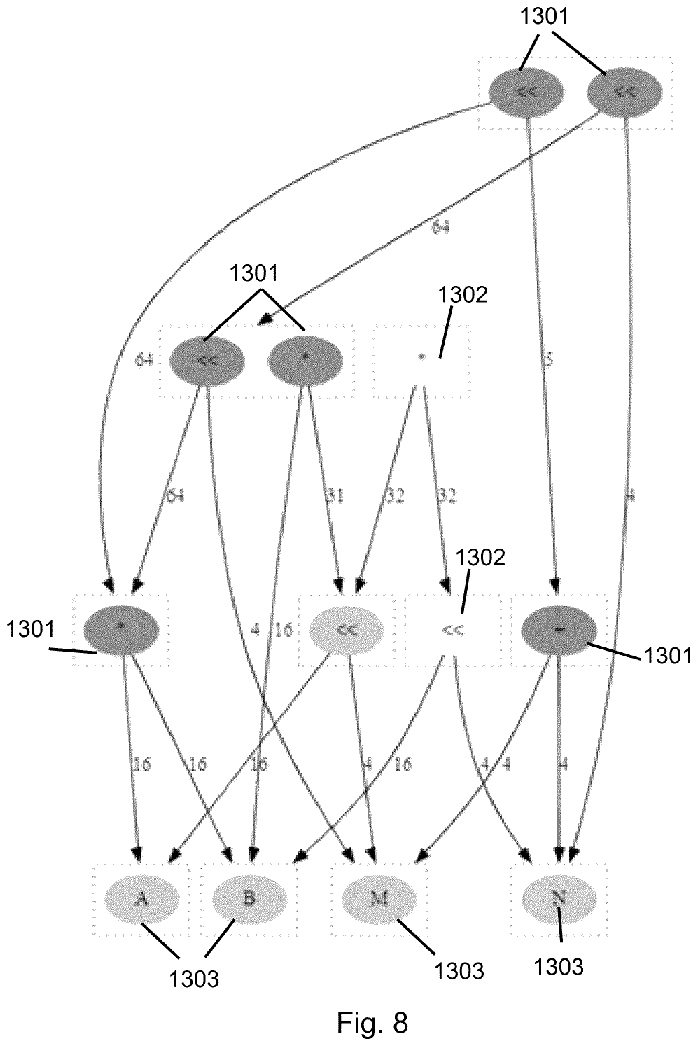

Rewrites are applied to both the specification and implementation designs simultaneously with the objective being to discover equivalent sub-expressions across the two designs. As rewrites are applied, new nodes are added to the e-graph and the e-classes grow, as seen in FIG. 8.

FIG. 8 shows an example where, after two stages of rewriting, the e-graph contains several equivalent implementations of impl (1301), one of which shares an operator 1312 with spec 1302. Rewriting 130 the third graph is done according to a cost function. The cost function may bias rewriting the third graph with one or more logically equivalent operators shared between the first and second designs when a plurality of logically equivalent operators are determined. Determining the one or more logically equivalent operators may be based on a pre-defined set of logically equivalent transformations between operators.

The first, second, and third graphs may include 115 a bit-width of the operands in the graph representation as values of the edges between the vertices representing the operands and the vertices representing the operators accessing the operands. These edge labels may be used to determine logical equivalence between operators, with some operators only available, or efficient, for a sub-set of the supported bit-widths.

In particular, determining the one or more logically equivalent operators may be based on the bit-width of the operands. The bit-widths being used may change if the proposed concept is applied to parametrizable circuit designs. In other words, circuit designs that can be adapted according to a parameter, with the parameter specifying, explicitly or implicitly, the bit-width.

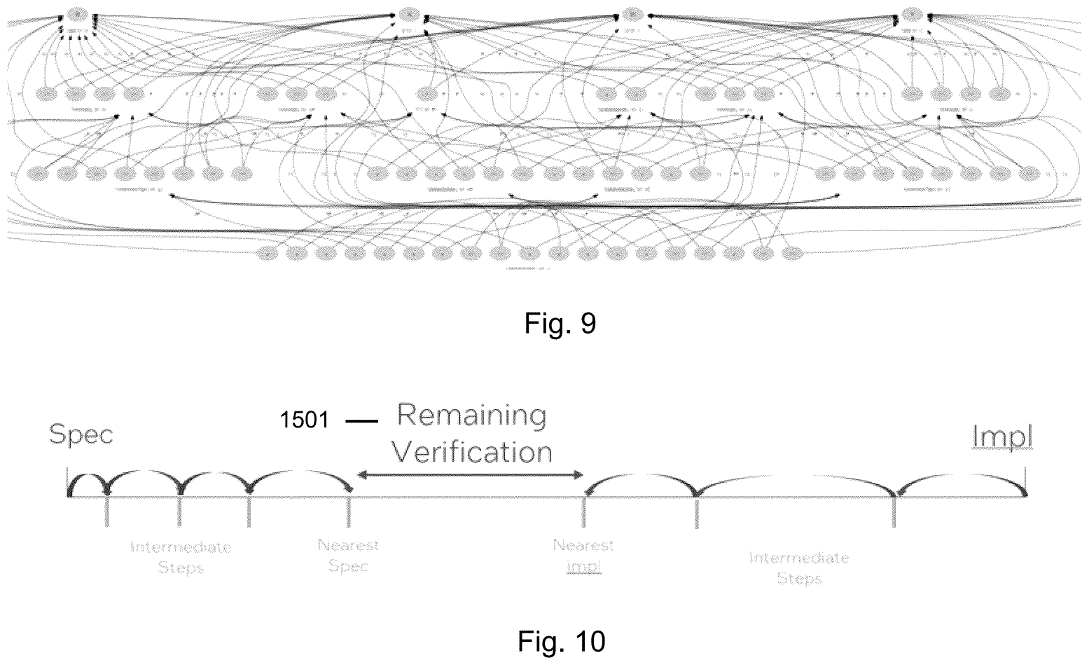

FIG. 9 shows an example where, after five rewriting stages, a large e-graph containing many designs is constructed. All nodes are shared (as denoted by their shared color) as a sequence of rewrites transforming specification to implementation is discovered.

Once the e-graph has saturated or reached a timeout, the e-graph represents two sets of equivalent designs, one for the specification and one for the implementation. From the e-graph we now seek to extract two designs that share the maximum number of common nodes.

Extracting 140 one or more shared designs may comprise using an integer linear program solver. At the extraction stage equivalent designs for both the specification and implementation in the e-graph that shares the greatest number of operators may be found. To achieve this, a cost function is constructed that heavily biases towards using shared nodes and penalizes non-shared nodes. The cost function may ensure that the rewritten designs of the specification and implementation share the maximum amount of nodes possible, and when two designs share the same amount of nodes, the simplest one is chosen of rextraction. Then an integer linear program solver may be used to extract the two nearest equivalent designs. If the two designs are found in the same e-class, meaning a path or rewrites was found between the two designs, then the two designs are identical. I

FIG. 10 shows spectrum visualization of designs resulting from extraction. The method may further comprise generating 150 a set of RTL representations of the plurality of shared designs. The set of RTL representations may comprise a nearest first (e.g. specification) design and a nearest second (e.g. implementation) design. The processing circuitry may be configured to output the generated RTL representation or representations, e.g., via a computer-readable medium or via a signal comprising the respective RTL representation or representations.

The interface circuitry 12 or means for communicating 12 may correspond to one or more inputs and/or outputs for receiving and/or transmitting information, which may be in digital (bit) values according to a specified code, within a module, between modules or between modules of different entities. For example, the interface circuitry 12 or means for communicating 12 may comprise circuitry configured to receive and/or transmit information.

For example, the processing circuitry 14 or means for processing 14 may be implemented using one or more processing units, one or more processing devices, any means for processing, such as a processor, a computer or a programmable hardware component being operable with accordingly adapted software. In other words, the described function of the processing circuitry 14 or means for processing may as well be implemented in software, which is then executed on one or more programmable hardware components. Such hardware components may comprise a general-purpose processor, a Digital Signal Processor (DSP), a micro-controller, etc.

For example, the storage circuitry 16 or means for storing information 16 may comprise at least one element of the group of a computer readable storage medium, such as a magnetic or optical storage medium, e.g., a hard disk drive, a flash memory, Floppy-Disk, Random Access Memory (RAM), Programmable Read Only Memory (PROM), Erasable Programmable Read Only Memory (EPROM), an Electronically Erasable Programmable Read Only Memory (EEPROM), or a network storage.

For example, the computer system 100 may be a workstation computer system, i.e., a computer system that is used locally by an individual engineer, or a server computer system, i.e., a computer system being used to serve functionality, such as the selection of the representation and the generation of the code, to one or client computers.

FIG. 10 shows the design spectrum and gap 1501 that is sought to be closed. If a complete rewrite path between spec and impl is found then “Nearest Spec” and “Nearest Impl” designs will be identical. However, even if a single logically equivalent design cannot be found, the remaining verification problem is substantially smaller.

The method may further comprise validating 160 the first and the second design by providing the nearest first and the nearest second design to an equivalence checker. From the e-graph, the sequence of intermediate designs passed through to reach “Nearest Spec” from “Spec” and “Nearest Impl” from “Impl” can be extracted.

The set of RTL representations may comprise a plurality of intermediate first and intermediate second designs. At each intermediate stage an RTL can be built and these intermediate stages (separated by one small transformation) can be passed to a commercial equivalence checker to validate their equivalence. Each check may be far simpler than the whole design as the complete equivalence check is broken into a sequence of smaller sub-proofs. This may also provide an additional layer of trust as equivalence can be verified at multiple stages. Alternatively, the correctness of the rewrites could be formally proven to provide verified guarantees.

Validating 160 may further comprise validating the first and the second design by providing the nearest and the intermediate first designs and the nearest and the intermediate second designs to an equivalence checker. Increasing the number of designs passed to equivalence checker may provide greater opportunities for finding an equivalent design.

Raising the abstraction level to apply e-graphs with bitvector manipulating rewrites can greatly enhance the capabilities of existing equivalence checking tools. This may enhance formal equivalence checking tools for the industry.

Another embodiment of the method may verify the equivalence of a first and a second design of a circuit. The method may comprise generating a first graph representation of an RTL representation of the first design and a second graph representation of an RTL representation of the second design, wherein the first and second graph representation each comprise a first set of vertices representing operators and a second set of vertices representing operands of the corresponding RTL representation, wherein each graph representation further comprises edges between the vertices representing relationships between the operators and operands. The method joining the first and second graph representations into a third graph and rewriting the third graph to add a plurality of logically equivalent designs to the first and second design, wherein rewriting the third graph comprises determining, for one or more operators represented by the one or more vertices of a first set of vertices of the third graph, one or more logically equivalent operators. The method determining a shared design from the plurality of logically equivalent designs of the third graph, wherein the shared design comprises a plurality of vertices shared between the equivalent designs of the first and second graphs of the circuit.

The method may further comprise determining the equivalence of the first and the second design of the circuit based on the shared design. The method further comprising generating an RTL representations of the shared design. The method may further comprise validating the shared design with an equivalence checker. Extracting the shared design may comprise using an integer linear program solver. Rewriting the third graph may be done according to a cost function. The cost function may bias rewriting the third graph with one or more logically equivalent operators shared between the first and second designs when a plurality of logically equivalent operators are determined.

Determining the one or more logically equivalent operators based on a pre-defined set of logically equivalent transformations between operators. The first, second, and third graphs may include a bit-width of the operands in the graph representation as values of the edges between the vertices representing the operands and the vertices representing the operators accessing the operands. Determining the one or more logically equivalent operators based on the bit-width of the operands.

More details and aspects of the apparatus, device, method, computer program, and computer system are mentioned in connection with the proposed concept, or one or more examples described above or below (e.g., FIGS. 2 to 10). The apparatus, device, method, computer program, and computer system may comprise one or more additional optional features corresponding to one or more aspects of the proposed concept, or one or more examples described above or below.

Various examples of the present disclosure relate to a concept for an equality graph (e-graph)-based automatic RTL exploration, which may be used for capturing logic synthesis data-path improvements or optimizations. Various examples may address the challenge of providing a concept for a more efficient automatic circuit design improvement or optimization with a large design space exploration that may consider hardware implementation cost.

In the proposed concept, raising the level of abstraction of circuit design to a word level optimization (or improvement) problem, graph structures, such as equality graphs (e-graphs) may be used constructively rewrite the circuit, optionally including bit-widths as edge labels, thereby generating a dense representation of many different designs. By introducing non-standard operators representing complex data-path blocks, the e-graph may capture the merging capabilities of logic synthesis tools. This dense representation of designs may enable a more efficient design space exploration, generating architectures that logic synthesis can better optimize.

One aspect of the proposed concept relates to an application of modified e-graphs to RTL improvement or optimization. Additionally, the e-graphs may be modified to incorporate bit-widths (as edge labels). The e-graphs may be modified with appropriate nodes and rewrites to reflect logic synthesis, which may improve correlation with hardware design.

The proposed approach may match the manual improvement or optimization by a skilled hardware engineer, facilitating faster RTL bring-up and potentially discovering novel architectures. It may benefit RTL teams, incubator programs and fabrication services, thus providing an additional layer of service in circuit design with respect to improvement/optimization and implementation. For example, the approach may be deployed in an Electronic Design Automation (EDA) tool suite.

E-graphs provide a dense graphical representation of equivalence classes over expressions. They should be read bottom-up. FIG. 2 shows an illustration of an example of equality graph rewriting. Two examples can be seen in FIG. 2, where the second e-graph contains two nodes within a single equivalence class. Nodes (ellipses) represent operators/operands, and the dashed boxes represent equivalence classes. On the left side, the original graph 210 is shown (with the operation x×2). A rewrite rule 220 (x×2→x<<1) is used to insert the second operation in the modified graph 230. The left-hand e-graph 210 contains only x×2, but the right-hand e-graph 220 contains x×2 and x<<1, which are equivalent according to the rewrite. This implies that the distinct expressions represented by these nodes, namely x×2 and x<<1, are equivalent.

Rewrites of the form l→r define equivalence relations between expressions, l˜r. Constructively applying rewrites to the e-graph, allows the e-graph to grow monotonically, so that the rewritten e-graph contains both the left- and right-hand side of the rewrite in the same equivalence class. In FIG. 2, the rewrite, x×2→x<<1, defines an equivalence of these two expressions. The right-hand side is added to the e-graph in the same class as the left-hand side.

The e-graph data structure is powerful as it contains the full history of all the rewritten expressions and can contain infinitely many equivalent expressions.

FIG. 3 shows a flow chart of an example of a transformation of a first and second register transfer level design into a graph representation, and of an extraction of a register transfer level representation. The RTL 310 is transformed into an e-graph 320, on which re-writes 325 are applied, leading to a dense representation of equivalent designs 330, which can then be used to generate extract a shared RTL representation 340. The diagram of FIG. 3 thus illustrates how two RTLs design can be transformed into a dense representation of infinitely many equivalent designs and a shared RTL can be extracted.

Combinational RTL operating on bit vectors can be viewed as a dataflow graph, with bit-widths as edge labels. This enables converting RTL into an initial e-graph. Applying rewrites to this e-graph, the space of equivalent designs can be explored, whilst maintaining a history of all the generated designs generated. For example, the rewrites may be a function of bit-width. The final e-graph may contain a dense representation of potentially infinitely many equivalent RTL designs. Examples of the operators used in the rewrites are described in FIG. 4, along with the associated architecture for more complex operators, which is relevant for operator costing.

FIG. 4 shows a table of an example of operators used to improve arithmetic circuits, along with associated architectures for more complex operators. For example, the operators being used may include left/right shift, addition/subtraction, negation, multiplication, multiplexer, non/inversion, concatenate/truncate, comparison, summation, multiplex array (MUXAR) and fused multiply add (FMA).

The rewrites that can be conditionally applied to the e-graph (e.g., if the matched bit-widths satisfy certain constraints), are described in FIG. 5. FIG. 5 shows a table of an example of a (bit-width dependent) set of rewrites. Such rewrites facilitate design space exploration and enable complex merging of operations. The rewrites of FIG. 5 use a left subscript notation, ₚx, denotes a bit vector x of length p bits. The * operator represents any from the set {+,×} in this context. Square brackets represent Verilog bit slicing, where a[x: y] means to take bits x down to y of a.

The proposed rewrites capture the capabilities of the logic synthesis tools to merge adjacent operators into a single data path block, often saving the cost of additional carry-propagate adders. They are described in the “Merging Ops” class in FIG. 5. For example, the MUXAR (multiplex arrays) operator exploits the identity below to implement multiplication involving a variable and its inverse in a single Datapath block. Square brackets indicate bit slicing here.

$$a * b + \overline{a} * c = {\sum }_{i = 0}^{n} ( a [ i ] ? \text{b:c} ) ≪ i$$

Including bit-widths in the e-graph optimization enables to correctly evaluate the cost of implementing different operators in hardware. Using a relevant hardware cost metric that can differentiate between designs, an improved or optimal architecture can be selected from the set of designs in the e-graph. Since the e-graph is fundamentally based on equivalence, the selected architecture may be equivalent to the original design by construction.

More details and aspects of the concept for equality graph based automatic RTL exploration are mentioned in connection with the proposed concept or one or more examples described above or below (e.g., FIG. 1a to 1b, 6 to 10). The concept for equality graph based automatic RTL exploration may comprise one or more additional optional features corresponding to one or more aspects of the proposed concept, or one or more examples described above or below.

The proposed concept may be applied for automatic bit-width dependent improved or optimal architecture selection using e-graph optimization.

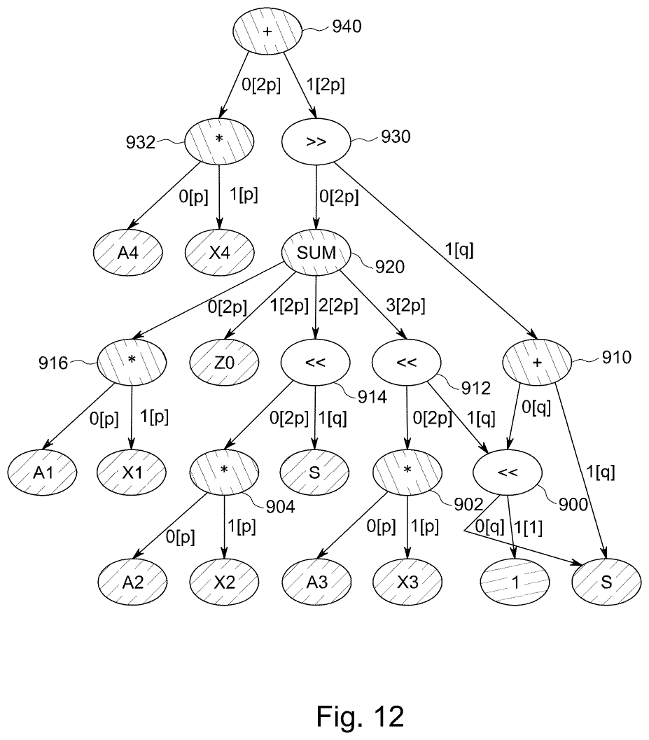

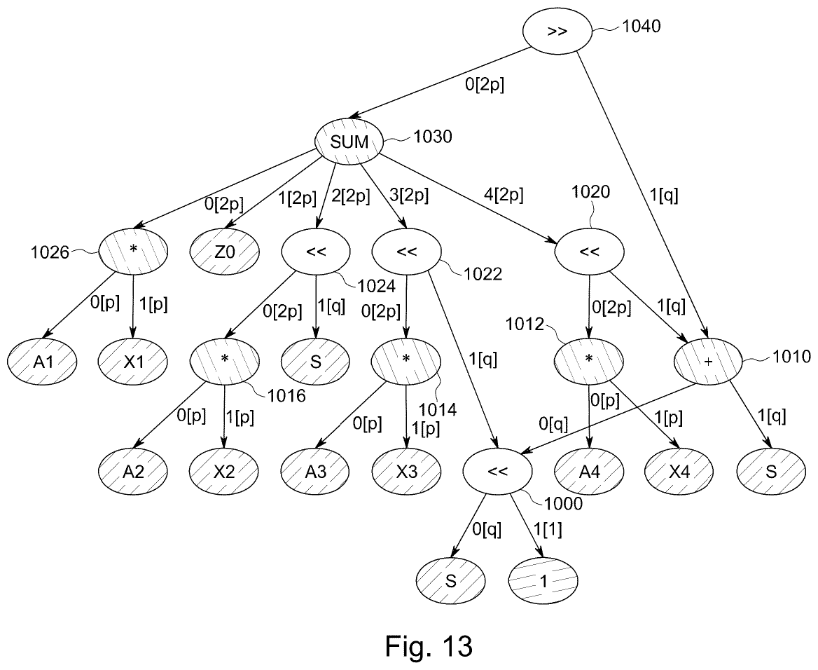

Different improved or optimized architectures emerge as the bit-width parameterization of a design changes because the tradeoffs of a given transformation are bit-width dependent. Even in a simple example, a 4-tap FIR filter, three architectures emerge as the bit-width of the inputs' ranges from 4 bits up to 64 bits (in 4-bit increments). FIGS. 11 to 13 show the differences between the output architectures. FIGS. 11 to 13 shows graphs of examples of different representations of a circuit. FIG. 11 shows architecture 0, which may be considered improved or optimal for a bit-width of 4. FIG. 12 shows architecture 1, which may be considered improved or optimal for bit-widths 8 to 28 and 36 to 48. FIG. 13 shows architecture 2, which may be considered improved or optimal for bit-widths 32 and 52 to 64.

The architecture 0 shown in FIG. 11 comprises the operation 800 (A1×X1), with both operands having the bit-width p, operation 810 (the result of operation 800+C), with both operands having the bit-width 2p, operation 820 (the result of operation 810 right-shifted (>>) by S, with the result of operation 810 having a bit-width of 2p and S (the number of bit shifts) having a bit-width of q, operation 825 (A2×X2), with both operands having the bit-width p, operation 830 (the result of operation 825+the result of operation 820), with both operands having the bit-width 2p, operation 840 (the result of operation 830 right-shifted by S), with the result of operation 830 having a bit-width of 2p and S (the number of bit shifts) having a bit-width of q, operation 845 (A3×X3), with both operands having the bit-width p, operation 850 (the result of operation 845+the result of operation 840, with both operands having the bit-width 2p, operation 860 (the result of operation 850 right-shifted by S), with the result of operation 850 having a bit-width of 2p and S (the number of bit shifts) having a bit-width of q, operation 865 (A4×X4), with both operands having the bit-width p, and operation 870 (the result of operation 865+the result of operation 860), with both operands having the bit-width 2p.

The graph of FIG. 12 is logically equivalent to the graph of FIG. 11. The architecture 1 shown in FIG. 12 comprises the operation 900 (S<<1), with S having a bit-width of q and 1 having a bit-width of 1, operation 902 (A3×X3), with both operands having the bit-width p, operation 904 (A2×X2), with both operands having the bit-width p, operation 910 (the result of operation 900+S), with both operands having the bit-width q, operation 912 (the result of operation 902 shifted by the result of operation 900), with the result of operation 902 having a bit-width of 2p and the result of operation 900 having the bit-width q, operation 914 (the result of operation 904<<S), with the result of operation 904 having a bit-width of 2p and S having a bit-width of q, operation 916 (A1×X1), with both operands having the bit-width p, operation 920 (a sum of the results of operations 912, 914, 916 and Z0), with the operands each having a bit-width of 2p, operation 930 (the result of operation 920 right-shifted (>>) by the result of operation 910), with the result of operation 920 having a bit-width of 2p and the result of operation 910 having a bit-width of q, operation 932 (A4×X4), with both operands having the bit-width p, and operation 940 (the result of operation 932+the result of operation 930), with both operands having the bit-width 2p.

The graph of FIG. 13 is logically equivalent to the graphs of FIGS. 11 and 12. The architecture 2 shown in FIG. 13 comprises operation 1000 (S<<1), with S having a bit-width of q and l having a bit-width of l, operation 1010 (the result of operation 1000+S), with both operands having a bit-width of q, operation 1012 (A4×X4), with both operands having the bit-width p, operation 1014 (A3×X3), with both operands having the bit-width p, operation 1016 (A2×X2), with both operands having the bit-width p, operation 1020 (the result of operation 1012<<the result of operation 1010), with the result of operation 1012 having a bit-width of 2p and the result of operation 1010 having a bit-width of q, operation 1022 (the result of operation 1014<<the result of operation 1000), with the result of operation 1014 having a bit-width of 2p and the result of operation 1000 having a bit-width of q, operation 1024 (the result of operation 1016<<S), with the result of operation 1016 having a bit-width of 2p and S having a bit-width of q, operation 1026 (A1×X1), with both operands having the bit-width p, operation 1030 (the sum of operations 1020, 1022, 1024, 1026 and Z0), with each operand having a bit-width of 2p, and operation 1040 (the result of operation 1030>>the result of operation 1010), with the result of operation 1030 having a bit-width of 2p and the result of operation 1010 having a bit-width of q.

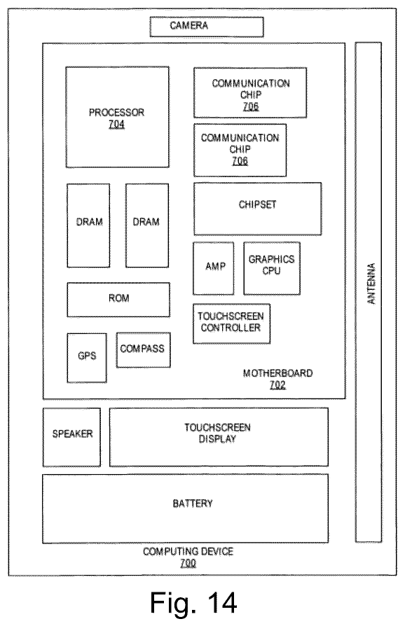

FIG. 14 illustrates a computing device in accordance with one implementation of the disclosed embodiments. The computing device 700 houses a board 702. The board 702 may include a number of components, including but not limited to a processor 704 and at least one communication chip 706. The processor 704 is physically and electrically coupled to the board 702. In some implementations, the at least one communication chip 706 is also physically and electrically coupled to the board 702. In further implementations, the communication chip 706 is part of the processor 704. Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter-range wireless communications such as Wi-Fi and Bluetooth and a second communication chip 706 may be dedicated to longer-range wireless communications such as GPS, EDGE, GPRS, CDMA, WiMAX, LTE, Ev-DO, and others. The processor 704 of the computing device 700 includes an integrated circuit die packaged within the processor 704. In some implementations of the disclosed embodiments, the integrated circuit die of the processor includes one or more devices that are assembled in an ePLB or cWLB-based POP package that includes a mold layer directly contacting a substrate, in accordance with implementations of the disclosed embodiments. The term “processor” may refer to any device or portion of a device that processes electronic data from registers and/or memory to transform that electronic data into other electronic data that may be stored in registers and/or memory. The communication chip 706 also includes an integrated circuit die packaged within the communication chip 706. In accordance with another implementation of the disclosed embodiments, the integrated circuit die of the communication chip includes one or more devices that are assembled in an ePLB or cWLB-based POP package that includes a mold layer directly contacting a substrate, in accordance with implementations of the disclosed embodiments.

More details and aspects of the concept for generating a plurality of shared designs relating to designs of a circuit are mentioned in connection with the proposed concept or one or more examples described above or below. The concept for automatic bit-width dependent design validation using e-graph optimization may comprise one or more additional optional features corresponding to one or more aspects of the proposed concept, or one or more examples described above or below.

An example (e.g. example 1) relates to a method for generating a plurality of shared designs relating to a first and a second design of a circuit. The method comprising: generating a first graph representation of an RTL representation of the first design and a second graph representation of an RTL representation of the second design, wherein the first and second graph representation each comprise a first set of vertices representing operators and a second set of vertices representing operands of the corresponding RTL representation, wherein each graph representation further comprises edges between the vertices representing relationships between the operators and operands; joining the first and second graph representations into a third graph; rewriting the third graph to add a plurality of logically equivalent designs to the first and second design, wherein rewriting the third graph comprises determining, for one or more operators represented by the one or more vertices of a first set of vertices of the third graph, one or more logically equivalent operators; extracting a plurality of shared designs from the plurality logically equivalent designs of the third graph, wherein each shared design comprises a plurality of vertices shared between the equivalent designs of the first and second graphs of the circuit.

Another example (e.g. example 2) relates to a previously described example (e.g. example 1), further comprising generating a set of RTL representations of the plurality of shared designs.

Another example (e.g. example 3) relates to a previously described example (e.g. example 2), wherein the set of RTL representations comprises a nearest first design and a nearest second design.

Another example (e.g. example 4) relates to a previously described example (e.g. example 3), wherein the method further comprises validating the first and the second design by providing the nearest first and the nearest second design to an equivalence checker.

Another example (e.g. example 5) relates to a previously described example (e.g. one of the examples 3 or 4), wherein the set of RTL representations further comprises a plurality of intermediate first and intermediate second designs.

Another example (e.g. example 6) relates to a previously described example (e.g. example 5), wherein the method further comprises validating the first and the second design by providing the nearest and the intermediate first designs and the nearest and the intermediate second designs to an equivalence checker.

Another example (e.g. example 7) relates to a previously described example (e.g. one of the examples 1-6), wherein extracting one or more shared designs comprises using an integer linear program solver.

Another example (e.g. example 8) relates to a previously described example (e.g. one of the examples 1-7), wherein rewriting the third graph is done according to a cost function.

Another example (e.g. example 9) relates to a previously described example (e.g. example 8), wherein the cost function biases rewriting the third graph with one or more logically equivalent operators shared between the first and second designs when a plurality of logically equivalent operators are determined.

Another example (e.g. example 10) relates to a previously described example (e.g. one of the examples 1-9), wherein the determining the one or more logically equivalent operators based on a pre-defined set of logically equivalent transformations between operators.

Another example (e.g. example 11) relates to a previously described example (e.g. one of the examples 1-10), wherein the first, second, and third graphs include a bit-width of the operands in the graph representation as values of the edges between the vertices representing the operands and the vertices representing the operators accessing the operands.

Another example (e.g. example 12) relates to a previously described example (e.g. example 11), wherein determining the one or more logically equivalent operators based on the bit-width of the operands.

An example (e.g. example 13) relates to non-transitory, computer-readable medium comprising a program code that, when the program code is executed on a processor, a computer, or a programmable hardware component, causes the processor, the computer, or the programmable hardware component to perform the method of a previously described example (e.g. one of the examples 1-12).

An example (e.g. example 14) relates to an apparatus for generating a plurality of shared designs relating to a first and a second design of a circuit, the apparatus comprising processing circuitry configured to: generate a first graph representation of an RTL representation of the first design and a second graph representation of an RTL representation of the second design, wherein the first and second graph representation each comprise a first set of vertices representing operators and a second set of vertices representing operands of the corresponding RTL representation, wherein each graph representation further comprises edges between the vertices representing relationships between the operators and operands; join the first and second graph representations into a third graph; rewrite the third graph to add a plurality of logically equivalent designs to the first and second design, wherein rewriting the third graph comprises determining, for one or more operators represented by the one or more vertices of a first set of vertices of the third graph, one or more logically equivalent operators; extract a plurality of shared designs from the plurality logically equivalent designs of the third graph, wherein each shared design comprises a plurality of vertices shared between the equivalent designs of the first and second graphs of the circuit.

Another example (e.g. example 15) relates to a previously described example (e.g. example 14), where in the processing circuitry is further configured to generate a set of RTL representations of the plurality of shared designs.

Another example (e.g. example 16) relates to a previously described example (e.g. example 15), wherein the set of RTL representations comprises a nearest first and a nearest second design.

Another example (e.g. example 17) relates to a previously described example (e.g. example 16), wherein the processing circuitry is configured to validate the first and the second design by providing the nearest first and the nearest second design to an equivalence checker.

Another example (e.g. example 18) relates to a previously described example (e.g. one of the examples 16 or 17), wherein the set of RTL representations further comprises a plurality of intermediate first and intermediate second designs.

Another example (e.g. example 19) relates to a previously described example (e.g. example 18), wherein the processing circuitry is configured to validate the first and the second design by providing the nearest and intermediate first designs and the nearest and intermediate second designs to an equivalence checker.

Another example (e.g. example 20) relates to a previously described example (e.g. one of the examples 16-19), wherein extracting one or more equivalent designs comprises using an integer linear program solver.

Another example (e.g. example 21) relates to a previously described example (e.g. one of the examples 16-20), wherein rewriting the equivalence graph is done according to a cost function.

Another example (e.g. example 22) relates to a previously described example (e.g. example 21), wherein the cost function biases the inclusion of one or more logically equivalent operators in the equivalence graph when the operators are shared between the first and the second designs.

An example (e.g. example 23) relates to a method for verifying the equivalence of a first and a second design of a circuit, the method comprising: generating a first graph representation of an RTL representation of the first design and a second graph representation of an RTL representation of the second design, wherein the first and second graph representation each comprise a first set of vertices representing operators and a second set of vertices representing operands of the corresponding RTL representation, wherein each graph representation further comprises edges between the vertices representing relationships between the operators and operands; joining the first and second graph representations into a third graph; rewriting the third graph to add a plurality of logically equivalent designs to the first and second design, wherein rewriting the third graph comprises determining, for one or more operators represented by the one or more vertices of a first set of vertices of the third graph, one or more logically equivalent operators; determining a shared design from the plurality of logically equivalent designs of the third graph, wherein the shared design comprises a plurality of vertices shared between the equivalent designs of the first and second graphs of the circuit.

Another example (e.g. example 24) relates to a previously described example (e.g. example 23), wherein the method further comprises determining the verifying the equivalence of the first and the second design of the circuit based on the shared design.

Another example (e.g. example 25) relates to a previously described example (e.g. one of the examples 23 or 24), further comprising generating an RTL representations of the shared design.

Another example (e.g. example 26) relates to a previously described example (e.g. one of the examples 23-25), wherein the method further comprises validating the shared design with an equivalence checker.

Another example (e.g. example 27) relates to a previously described example (e.g. one of the examples 23-26), wherein extracting the shared design comprises using an integer linear program solver.

Another example (e.g. example 28) relates to a previously described example (e.g. one of the examples 23-27), wherein rewriting the third graph is done according to a cost function.

Another example (e.g. example 29) relates to a previously described example (e.g. one of the examples 23-28), wherein the cost function biases rewriting the third graph with one or more logically equivalent operators shared between the first and second designs when a plurality of logically equivalent operators are determined.

Another example (e.g. example 30) relates to a previously described example (e.g. one of the examples 23-29), wherein the determining the one or more logically equivalent operators based on a pre-defined set of logically equivalent transformations between operators.

Another example (e.g. example 31) relates to a previously described example (e.g. one of the examples 23-30), wherein the first, second, and third graphs include a bit-width of the operands in the graph representation as values of the edges between the vertices representing the operands and the vertices representing the operators accessing the operands.

Another example (e.g. example 32) relates to a previously described example (e.g. one of the examples 23-31), wherein determining the one or more logically equivalent operators based on the bit-width of the operands.

An example (e.g. example 33) relates to a non-transitory, computer-readable medium comprising a program code that, when the program code is executed on a processor, a computer, or a programmable hardware component, causes the processor, the computer, or the programmable hardware component to perform the method of a previously described example (e.g. one of the examples 23-32).

An example (e.g. example 34) is a system comprising an apparatus, computer-readable medium, or circuitry for performing a method of a previously described example (e.g. one of the examples 1-33).

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor, or other programmable hardware component. Thus, steps, operations, or processes of different ones of the methods described above may also be executed by programmed computers, processors, or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example, as well as other non-transitory computer readable mediums. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations, or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C #, Java, Perl, Python, JavaScript, Adobe Flash, C #, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

The disclosed methods, apparatuses, and systems are not to be construed as limiting in any way. Instead, the present disclosure is directed toward all novel and nonobvious features and aspects of the various disclosed examples, alone and in various combinations and sub combinations with one another. The disclosed methods, apparatuses, and systems are not limited to any specific aspect or feature or combination thereof, nor do the disclosed examples require that any one or more specific advantages be present, or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A method for generating a plurality of shared designs relating to a first and a second design of a circuit, the method comprising:
generating a first graph representation of an RTL representation of the first design and a second graph representation of an RTL representation of the second design,
wherein the first and second graph representation each comprise a first set of vertices representing operators and a second set of vertices representing operands of the corresponding RTL representation, wherein each graph representation further comprises edges between the vertices representing relationships between the operators and the operands;
joining the first and second graph representations into a third graph;
rewriting the third graph to add a plurality of logically equivalent designs to the first and second design, wherein rewriting the third graph comprises determining, for one or more operators represented by the one or more vertices of a first set of vertices of the third graph, one or more logically equivalent operators;
extracting a plurality of shared designs from the plurality logically equivalent designs of the third graph, wherein each shared design comprises a plurality of vertices shared between the equivalent designs of the first and second graphs of the circuit.

2. The method of claim 1, further comprising generating a set of RTL representations of the plurality of shared designs.

3. The method of claim 2, wherein the set of RTL representations comprises a nearest first design and a nearest second design.

4. The method of claim 3, wherein the method further comprises validating the first and the second design by providing the nearest first and the nearest second design to an equivalence checker.

5. The method of claim 3, wherein the set of RTL representations further comprises a plurality of intermediate first and intermediate second designs.

6. The method of claim 5, wherein the method further comprises validating the first and the second design by providing the nearest and the intermediate first designs and the nearest and the intermediate second designs to an equivalence checker.

7. The method of claim 1, wherein extracting one or more shared designs comprises using an integer linear program solver.

8. The method of claim 1, wherein rewriting the third graph is done according to a cost function.

9. The method of claim 8, wherein the cost function biases rewriting the third graph with one or more logically equivalent operators shared between the first and second designs when a plurality of logically equivalent operators are determined.

10. The method of claim 1, wherein the determining the one or more logically equivalent operators based on a pre-defined set of logically equivalent transformations between operators.

11. The method of claim 1, wherein the first, second, and third graphs include a bit-width of the operands in the graph representation as values of the edges between the vertices representing the operands and the vertices representing the operators accessing the operands.

12. The method of claim 11, wherein determining the one or more logically equivalent operators based on the bit-width of the operands.

13. A non-transitory, computer-readable medium comprising a program code that, when the program code is executed on a processor, a computer, or a programmable hardware component, causes the processor, the computer, or the programmable hardware component to perform the method of claim 1.

14. An apparatus for generating a plurality of shared designs relating to a first and a second design of a circuit, the apparatus comprising processing circuitry configured to:
generate a first graph representation of an RTL representation of the first design and a second graph representation of an RTL representation of the second design,
wherein the first and second graph representation each comprise a first set of vertices representing operators and a second set of vertices representing operands of the corresponding RTL representation, wherein each graph representation further comprises edges between the vertices representing relationships between the operators and operands;
join the first and second graph representations into a third graph;
rewrite the third graph to add a plurality of logically equivalent designs to the first and second design, wherein rewriting the third graph comprises determining, for one or more operators represented by the one or more vertices of a first set of vertices of the third graph, one or more logically equivalent operators;
extract a plurality of shared designs from the plurality logically equivalent designs of the third graph, wherein each shared design comprises a plurality of vertices shared between the equivalent designs of the first and second graphs of the circuit.

15. The apparatus of claim 14, where in the processing circuitry is further configured to generate a set of RTL representations of the plurality of shared designs, wherein the set of RTL representations comprises a nearest first and a nearest second design.

16. The apparatus of claim 15, wherein the processing circuitry is configured to validate the first and the second design by providing the nearest first and the nearest second design to an equivalence checker.

17. The apparatus of claim 15, wherein the set of RTL representations further comprises a plurality of intermediate first and intermediate second designs, wherein the processing circuitry is configured to validate the first and the second design by providing the nearest and intermediate first designs and the nearest and intermediate second designs to an equivalence checker.

18. The apparatus of claim 15, wherein extracting one or more equivalent designs comprises using an integer linear program solver.

19. The apparatus of claim 15, wherein rewriting the equivalence graph is done according to a cost function, wherein the cost function biases the inclusion of one or more logically equivalent operators in the equivalence graph when the operators are shared between the first and the second designs.
